(19) United States
(12) Patent Application Publication
(10) Pub. No.: US 2016/0268305 A1
(43) Pub. Date: Sep. 15, 2016

(54) ARRAY SUBSTRATE AND DISPLAY DEVICE

(71) Applicant: BOE TECHNOLOGY GROUP CO., LTD., Beijing (CN)

(72) Inventor: Xiang LIU, Beijing (CN)

(73) Assignee: BOE TECHNOLOGY GROUP CO., LTD., Beijing (CN)

(21) Appl. No.: 14/407,011

(22) PCT Filed: Dec. 17, 2013
(86) PCT No.: PCT/CN2013/089626

§ 371 Date: Dec. 10, 2014

(30) Foreign Application Priority Data
Aug. 1, 2013 (CN) 201310331981.3

(51) Int. Cl. H01L 27/12; H01L 23/535; H01L 23/528; H01L 23/532

(52) U.S. Cl. CPC H01L 27/124; H01L 23/53223; H01L 23/535; H01L 23/528

(57) ABSTRACT

Provided are an array substrate and a display device. The array substrate comprises a base substrate and a metal pattern on the base substrate. The metal pattern comprises a metal layer formed of a mixture of aluminum and a second metal, with a molar ratio of the second metal to the aluminum being lower than 1/99 in the metal layer. By controlling content of the second metal being lower than 1% in the metal layer, and applying the metal layer to a gate scanning line and a data scanning line, the present disclosure may suppress a phenomenon of generating a hillock in the gate scanning line and the data scanning line caused by being heated.

### TECHNICAL FIELD

The present invention relates to an array substrate and a display device.

### BACKGROUND

A thin film transistor-liquid crystal display (TFT-LCD) has advantages of a small size, low power consumption and radiation free, and plays a leading role in the current market of a flat panel display. As to TFT-LCD, the array substrate and the manufacturing process thereof determine its performances, as well as yield and price of a product thereof.

In general, an array substrate mainly includes a base substrate and a pixel unit on the base substrate, with the pixel unit mainly consisting of a gate scanning line, a data scanning line, a thin film transistor. The gate scanning line is used to transmit a scanning signal, and the data scanning line is used to transmit a data signal. To prevent a signal distortion produced during a signal transmitting process, a metal or a metal alloy having excellent conductivity is generally used as a material for the gate scanning line and the data scanning line. The material used for the gate scanning line and the data scanning line gradually changes into a pure aluminum (Al) material with a low resistivity from a conventional material with a high resistivity, such as chromium (Cr), molybdenum (Mo), aluminum-neodymium (AlNd). But, the pure Al film with the low resistivity has a disadvantage of poor thermostability, meaning that a hillock generates after the pure Al film with the low resistivity is heated to a certain extent. The hillock impales a gate insulation layer, which results in a short circuit occurring between the gate scanning line and a source electrode, a drain electrode, or between the gate scanning line and the data scanning line. A mechanism of a hillock generation is that: since a glass and the Al film have different coefficients of thermal expansion, the Al film swells and has a deformation when being heated, while because one side of the Al film close to the glass is confined, when a temperature reaches to a certain extent (generally 130 degrees Celsius), the Al film reaches the maximum limitation of internal compressive stress, thereby atoms in the Al film move to release internal stress, generally along a direction of the crystal boundary, by which the hillock generates.

Therefore, how to better suppress the hillock generation becomes to an urgent technique problem to be solved.

### SUMMARY OF THE INVENTION

The present disclosure provides an array substrate and a display device, which can suppress a hillock generation caused by a metal pattern of the array substrate being heated.

An array substrate, comprises a base substrate and a metal pattern on the substrate, wherein the metal pattern comprises a metal layer formed of a mixture of aluminum and a second metal, with a molar ratio of the second metal to the aluminum being lower than 1/99 in the metal layer.

The molar ratio of the second metal to the aluminum is between 1/999 and 1/199.

The second metal plays a role of pinning in the metal aluminum film, preventing an aluminum atom moving after being heated, by which can avoid the hillock generation.

The second metal is formed at a crystal boundary of a film formed of the aluminum.

The metal pattern has a double-layer structure, with a first layer close to the base substrate being the metal layer, and a second layer located on the first layer being a film layer formed of a material of molybdenum.

The metal pattern has a successively-stacked triple-layer structure, with a first layer close to the base substrate being a film layer formed of a material of molybdenum, a second layer located on the first layer being the metal layer, and a third layer located on the second layer being a film layer formed of a material of molybdenum, titanium or tantalum.

The second metal is neodymium, titanium, zirconium, tantalum, scandium or copper.

The metal pattern is at least one of a gate electrode, a gate scanning line, a data scanning line, a source electrode, a drain electrode.

The metal layer has a thickness ranging from 4000 Å to 8000 Å.

A display device, which comprises the array substrate.

The above technical solutions according to embodiments of the present disclosure have following advantageous effects:

In embodiments of the present disclosure, an alloy is formed by adding a trace amount of other metal elements to the aluminum (Al), such as neodymium (Nd), titanium (Ti), zirconium (Zr), tantalum (Ta), scandium (Sc) or copper (Cu), which can decrease cost. Furthermore, the other metal added plays a role of pinning in the crystals, which prevents Al atoms generating a hillock caused by being heated, and thus the yield of product can be improved when a triple-layer structure of the pure Al is used together, with approximately 1% to 8% of improvement.

### DETAILED DESCRIPTION

To make the objects, the technical solutions and the advantages of the present disclosure more apparent, detailed description will be given below in conjunction with specific embodiments.

An array substrate of the present disclosure includes a base substrate and a metal pattern on the base substrate, in which the metal pattern comprises a metal layer formed of a mixture of aluminum and a second metal, with a molar ratio of the second metal to the aluminum being lower than 1/99 in the metal layer.

The molar ratio of the second metal to the aluminum is between 1/999 and 1/199.

The second metal is formed at a crystal boundary of a film formed of the aluminum, which means that the film formed of the Al metal consists of crystal particles, the crystal boundary (which may be understood as a boundary of the crystal particles) is formed between adjacent crystal particles, and the second metal is formed at the crystal boundary. The second metal plays a role of pinning in the Al film, preventing the Al atoms moving after being heated, by which avoids the hillock generation.

The metal pattern has a double-layer structure, with a first layer close to the base substrate being the metal layer, and a second layer located on the first layer being a film layer formed of a material of molybdenum.

The metal pattern has a successively-stacked triple-layer structure, with a first layer close to the base substrate being a film layer formed of a material of molybdenum, a second layer located on the first layer being the metal layer, and a third layer located on the second layer being a film layer formed by a material of molybdenum, titanium or tantalum.

The second metal is neodymium, titanium, zirconium, tantalum, scandium or copper.

The metal pattern is at least one of a gate electrode, a gate scanning line, a data scanning line, a source electrode, a drain electrode.

An array substrate, at least includes a base substrate and a metal pattern on the base substrate, in which the metal pattern includes the metal layer according to embodiments of the present disclosure, the metal pattern at least is used to form a gate scanning line, a data scanning line and a thin film transistor, the thin film transistor at least includes a gate electrode, a source electrode and a drain electrode, at least one of the gate electrode, the gate scanning line, the data scanning line, the source electrode and the drain electrode includes the metal layer of the present disclosure.

Current two methods for solving the hillock generation in the Al film are: one method is to form a layer of metal film having a very high melting point on the Al metal layer, or on both sides thereof, the layer of metal film may suppress release of stress, so as to prevent the hillock generation; the other method is to form an alloy by adding other elements to Al, such as metals of Nd, Ti, Zr, Ta, Sc, Cu, and so on, the added metal is formed at a crystal boundary of a film formed of the metal aluminum, which plays a role of pinning, to prevent the hillock generation. When using AlNd alloy, having a relative higher molar ratio of Nd, generally between 2% to 20%, such content is generally regarded as being able to better control the hillock generation. But, adding a high-content of Nd to the prior AlNd alloy, not only results in a large resistivity of the AlNd alloy, but also causes a cost waste due to an expensive price of the Nd metal. In embodiments of the present disclosure, the AlNd alloy is added with a trace amount of Nd, controlling Nd having a content being lower than 1% in the AlNd alloy, by which a problem of the hillock generation is well solved. For example, when the content of Nd is controlled ranging from 0.1% to 0.5% in the AlNd alloy, a better effect can be achieved. If the metal film having the very high melting point is formed on both sides of the metal layer formed of the AlNd alloy, combining with the double-layer structure or the triple-layer structure, the problem of the hillock generation is well solved, with an improvement of yield being 1% to 8% comparing to the previous.

The present disclosure is further described below combining with the metal pattern of the present discourse being the double-layer structure and the triple-layer structure.

### Example 1

The present disclosure provided an array substrate, including a base substrate and a metal pattern on the base substrate, in which the metal pattern is a double-layer structure, with a first layer close to the substrate consisting of a second metal and Al; a second layer located on the first layer consisting of Mo. In the example of present disclosure, an alloy was formed by adding the second metal element to Al, such as Nd, Ti, Zr, Ta, Sc, Cu, and so on. The added metal was formed at a crystal boundary, playing a role of pinning, to prevent the hillock generation.

In which a molar ratio of the second metal to the aluminum was lower than 1/99 in the metal layer, for example, the molar ratio of the second metal to the aluminum was between 1/999 and 1/199. While reducing cost, it could also solve the problem that a small amount of hillocks are generated in prior art, so as to improve 1% to 8% yield of product.

Using a double-layer structure of Al/Mo, a layer of the metal film having a very high melting point was formed on the Al metal layer. The layer of the metal film could suppress release of stress to prevent the hillock generation. In addition, an alloy was formed by adding other elements to Al, for example, metals such as Nd, Ti, Zr, Ta, Sc, Cu, and so on, and the content of the other metals in the metal layer according to embodiments of the present disclosure is controlled between 0.1% to 0.5%, and the added metal was formed at the crystal boundary, playing a role of pinning, to prevent the hillock generation. Furthermore, adding the other metal with a small amount expends a relative lower cost, and the added metal not only has a low resistivity, but also could break the restriction for the Al film, that is, a thickness of a single-layer Al film can be increased from 2000 Å-4000 Å to 8000 Å. Comparing with existing alloy material, such material used in the present disclosure has a lower price and a lower resistivity; while comparing with pure Al film, such material used in the present disclosure has almost equivalent price and resistivity, but can improve the yield of a product.

In which, the second metal was Nd, Ti, Zr, Ta, Sc or Cu, which were metals all having a high melting point.

In which, the metal pattern was at least one of a gate electrode, a gate scanning line, a data scanning line, a source electrode, a drain electrode.

### Example 2

The present disclosure provided an array substrate, including a base substrate and a metal pattern deposited on the base substrate, in which the metal pattern had a successively-stacked triple-layer structure, with a first layer close to the base substrate consisting of Mo; a second layer located on the first layer consisting of a second metal and Al; a third layer located on the second layer consisting of Mo, Ti or Ta. The third layer was a barrier layer. In the example of present disclosure, an alloy was formed by adding other metal elements to Al, for example, metals such as Nd, Ti, Zr, Ta, Sc, Cu and so on. The added metal was formed at a crystal boundary, playing a role of pinning, to prevent the hillock generation.

In which, a molar ratio of the second metal to the aluminum was lower than 1/99 in the metal layer, for example, the molar ratio of the second metal to the aluminum was between 1/999 and 1/199. While reducing cost, it could also solve the generation of a small amount of hillocks in prior art, so as to improve 1% to 8% yield of product.

Using a triple-layer structure of Mo/Al/Mo, a layer of the metal film having a very high melting point was formed on both sides of the Al metal layer. The layer of the metal film could suppress release of stress to prevent the hillock generation. In addition, an alloy was formed by adding other elements to Al, for example, metals such as Nd, Ti, Zr, Ta, Sc, Cu, and so on, and the content of the other metals in the metal layer was controlled between 0.1% to 0.5%, and the added metal was formed at the crystal boundary, playing a role of pinning, to prevent the hillock generation. Furthermore, adding the other metals with a small amount expends a relative lower cost, the added metal not only has a low resistance, but also could break the restriction for the Al film, that is, a thickness of a single-layer Al film can be increased from 2000 Å-4000 Å to 8000 Å. Comparing with existing alloy material, such material used in the present disclosure has a lower price and a lower resistivity; while comparing with the pure Al film, such material used in the present disclosure has almost equivalent price and resistance, but can improve the yield of a product.

In which, the second metal was Nd, Ti, Zr, Ta, Sc or Cu, which were metals all having a high melting point.

In which, the metal pattern was at least one of a gate electrode, a gate scanning line, a data scanning line, a source electrode, and a drain electrode.

The present disclosure also provided a display device, including the array substrate. The display device may be any products or parts having a display function, such as a liquid crystal display panel, an electronic paper, an organic light emitting display (OLED) panel, a liquid crystal display television, a liquid crystal display, a digital photo frame, a mobile phone, a tablet personal computer, and so on.

In prior art, the pure Al film is generally used by panel manufacturers, which has a low resistivity with a low price. But a certain restriction is imposed on the thickness of the Al film, which is generally between 2000 Å-4000 Å. With increasing thickness of the Al film, the thickness of the top layer Mo also unceasingly increases, from 500 Å to 2000 Å. The hillock generation cannot be solved in this way fundamentally, there is still a small amount of hillocks generating.

In examples of the present disclosure, an alloy is formed by adding other metal elements to Al, for example, metals such as Nd, Ti, Zr, Ta, Sc, Cu and so on. The added metal was formed at a crystal boundary, playing a role of pinning, to prevent the hillock generation. The content of other metals according to embodiments of the present disclosure in the metal layer is controlled lower than 1%, for example between 0.1% to 0.5%, and a double-layer structure of Al/Mo or a triple-layer structure of Mo/Al/Mo is used, by which the number of the hillocks may be further decreased on the original basis, or the hillock generation may even be completely eradicated, so as to improve 1% to 8% yield of product. It may not only reduce badness caused by the hillock, and have a lower resistivity and a relative lower price comparing to existing alloy material, but also break the restriction for the Al film, that is, the thickness of the Al film can be increased to 8000 Å. Other metals may be metals such as Ti, Zr, Ta, Sc, Cu, and so on. The content of other metal in the Al film decreases to 1/20 of the originals. Comparing with existing alloy material, such material used in the present disclosure had a lower price and a lower resistivity; comparing with the pure Al film, such material used in the present disclosure had almost equivalent price and resistance, and can improve yield of product. The present disclosure can effectively solve a problem that: with increasing thickness of Al, for example more than 3000 Å, the triple-layer structure of Mo/Al/Mo cannot effectively suppress the hillock generation. The material used in the present disclosure may include a pure Al film added with a small amount of other metals such as Nd, having a content being lower than 1%, by which when using the triple-layer structure, such as Mo/Al/Mo, with a thickness of Al being larger than 3000 Å, the phenomenon of the hillock generation is avoided, which may effectively improve the yield.

The above are merely the preferred embodiments of the present invention. It should be noted that, a person skilled in the art may further make improvements and modifications without departing from the principle of the present invention, and these improvements and modifications shall also be considered as the scope of the present invention.

What is claimed is:

1. An array substrate, comprising a base substrate and a metal pattern on the base substrate, wherein the metal pattern comprises a metal layer formed of a mixture of aluminum and a second metal, with a molar ratio of the second metal to the aluminum being lower than 1/99 in the metal layer.

2. The array substrate according to claim 1, wherein the molar ratio of the second metal to the aluminum is between 1/999 and 1/199.

3. The array substrate according to claim 1, wherein the second metal is formed at a crystal boundary of a film formed of the aluminum.

4. The array substrate according to claim 1, wherein the metal pattern has a double-layer structure, with a first layer close to the base substrate being the metal layer, and a second layer located on the first layer being a film layer formed of a material of molybdenum.

5. The array substrate according to claim 1, wherein the metal pattern has a successively-stacked triple-layer structure, with a first layer close to the base substrate being a film layer formed of a material of molybdenum, a second layer located on the first layer being the metal layer, and a third layer located on the second layer being a film layer formed of a material of molybdenum, titanium or tantalum.

6. The array substrate according to claim 1, wherein the second metal is neodymium, titanium, zirconium, tantalum, scandium or copper.

7. The array substrate according to claim 1, wherein the metal pattern is at least one of a gate electrode, a gate scanning line, a data scanning line, a source electrode, and a drain electrode.

8. The array substrate according to claim 1, wherein the metal layer has a thickness ranging from 4000 Å to 8000 Å.

9. A display device, comprising the array substrate of claim 1.

10. The array substrate according to claim 2, wherein the metal pattern has a double-layer structure, with a first layer close to the base substrate being the metal layer, and a second layer located on the first layer being a film layer formed of a material of molybdenum.

11. The array substrate according to claim 2, wherein the metal pattern has a successively-stacked triple-layer structure, with a first layer close to the base substrate being a film layer formed of a material of molybdenum, a second layer located on the first layer being the metal layer, and a third layer located on the second layer being a film layer formed of a material of molybdenum, titanium or tantalum.

12. The array substrate according to claim 2, wherein the second metal is neodymium, titanium, zirconium, tantalum, scandium or copper.

13. The array substrate according to claim 2, wherein the metal pattern is at least one of a gate electrode, a gate scanning line, a data scanning line, a source electrode, and a drain electrode.

14. The array substrate according to claim 2, wherein the metal layer has a thickness ranging from 4000 Å to 8000 Å.

15. The display device according to claim 9, wherein the molar ratio of the second metal to the aluminum is between 1/999 and 1/199.

16. The display device according to claim 9, wherein the second metal is formed at a crystal boundary of a film formed of the aluminum.

17. The display device according to claim 9, wherein the metal pattern has a double-layer structure, with a first layer close to the base substrate being the metal layer, and a second layer located on the first layer being a film layer formed of a material of molybdenum.

18. The display device according to claim 9, wherein the metal pattern has a successively-stacked triple-layer structure, with a first layer close to the base substrate being a film layer formed of a material of molybdenum, a second layer located on the first layer being the metal layer, and a third layer located on the second layer being a film layer formed of a material of molybdenum, titanium or tantalum.

19. The display device according to claim 9, wherein the second metal is neodymium, titanium, zirconium, tantalum, scandium or copper.

20. The display device according to claim 9, wherein the metal layer has a thickness ranging from 4000 Å to 8000 Å.
